(19) United States
(12) Patent Application Publication
(10) Pub. No.: US 2025/0318104 A1
(43) Pub. Date: Oct. 9, 2025

(54) SEMICONDUCTOR STRUCTURE AND METHOD MANUFACTURING THE SAME

(71) Applicant: NANYA TECHNOLOGY CORPORATION, New Taipei city (TW)

(72) Inventor: Yi Long WONG, New Taipei City (TW)

(21) Appl. No.: 18/630,913

(22) Filed: Apr. 9, 2024

(51) Int. Cl. H10B 12/00

(52) U.S. Cl. CPC H10B 12/053; H10B 12/34

(57) ABSTRACT

Embodiments of this disclosure provide a semiconductor structure, including a plurality of active areas and a plurality of insulation areas. The plurality of active areas are disposed in a substrate and surrounded by a semiconductor material layer, and a surface of the semiconductor material layer contacting each of the active areas is rough. The insulation areas are disposed in the substrate and surrounding each of the active areas, each of the insulation areas includes the semiconductor material layer, a first barrier layer on the semiconductor material layer and an insulating layer over the first barrier layer, and a top surface of the semiconductor material layer and a bottom surface of the semiconductor material layer are rough. Additionally, a method of manufacturing a semiconductor structure is also provided in embodiments of this disclosure.

### BACKGROUND

### Field of Invention

The present disclosure relates to a semiconductor structure and a method of manufacturing the same. More particularly, the present disclosure relates to semiconductor structure and a method of manufacturing the same including a barrier layer between a semiconductor material layer and an insulating layer.

### Description of Related Art

As electronic devices become lighter and thinner, semiconductor devices, such as dynamic random access memory (DRAM) become more highly integrated. Further, the performance of the DRAM is improved via shortening the pitch between the semiconductor structures in the DRAM. In addition to increasing the difficulty of the manufacturing process, the components in the semiconductor structures are also prone to leakage resulting from too close distances because of shrinking the size of the semiconductor structure.

As a result, in the semiconductor manufacturing process, how to reduce the leakage to improve the process yield of the semiconductor structure has become an important issue.

### SUMMARY

Embodiments of this disclosure provide a method of manufacturing a semiconductor structure, including the following steps. A plurality of trenches are formed in a substrate. A semiconductor material layer is formed on an inner surface of each of the plurality of trenches and a top surface of the substrate, and the semiconductor material layer has an inner rough surface contacting the substrate and an outer rough surface exposing by each of the plurality of trenches. A first barrier layer is deposited on the outer rough surface of the semiconductor material layer, and an outer surface of the first barrier layer is even. A second barrier layer is deposited on the first barrier layer.

In some embodiments, the first barrier layer comprises oxide, and the second barrier layer comprises the oxide.

In some embodiments, a content of the oxide of the second barrier layer is different from a content of the oxide of the first barrier layer.

In some embodiments, a temperature for forming the first barrier layer is greater than a temperature for forming the second barrier layer.

In some embodiments, chloride is produced during forming the semiconductor material layer, and the inner rough surface and the outer rough surface of the semiconductor material layer are roughened by the chloride.

In some embodiments, an inner surface of the first barrier layer contacting the outer rough surface of the semiconductor material layer and the outer rough surface of the semiconductor material layer are conformal.

In some embodiments, a thickness of the semiconductor material layer is greater than a thickness of the first barrier layer.

In some embodiments, the method further includes the following steps. An insulating layer is deposited on the second insulating layer to form a plurality of insulation areas. The insulating layer is planarized until exposing a topmost surface of the semiconductor material layer to a plurality of active areas adjacent to each of the plurality of insulation areas.

In some embodiments, the topmost surface of the semiconductor material layer, a top surface of the first barrier layer, a top surface of the second barrier layer and a top surface of the insulating layer are coplanar.

In some embodiments, the method further includes the following step. A plurality of word line structures are formed in the plurality of active areas after depositing the insulating layer.

Embodiments of this disclosure provide a semiconductor structure, including a plurality of active areas and a plurality of insulation areas. The plurality of active areas are disposed in a substrate and surrounded by a semiconductor material layer, and a surface of the semiconductor material layer contacting each of the plurality of active areas is rough. The plurality of insulation areas are disposed in the substrate and surrounding each of the plurality of active areas, each of the plurality of insulation areas includes the semiconductor material layer, a first barrier layer on the semiconductor material layer and an insulating layer over the first barrier layer, and a top surface of the semiconductor material layer and a bottom surface of the semiconductor material layer are rough.

In some embodiments, a top surface of the semiconductor material layer is higher than a top surface of the substrate.

In some embodiments, a top surface of the semiconductor material layer is even and coplanar with a top surface of the insulating layer.

In some embodiments, each of the plurality of insulation areas further includes a second barrier layer, and the second barrier layer is disposed between the first barrier layer and the insulating layer.

In some embodiments, one surface of the first barrier layer contacting a surface of the second barrier layer is even, and the other surface of the first barrier layer contacting the other surface of the semiconductor material layer disposed on a sidewall of each of the active areas are conformal.

In some embodiments, a thickness of the semiconductor material layer is from 55 angstroms to 80 angstroms.

In some embodiments, a thickness of the first barrier layer is from 15 angstroms to 20 angstroms.

In some embodiments, the semiconductor structure further includes a plurality of word line structures and a plurality of source/drain areas. The plurality of word line structures extend through the insulation areas and the active areas, and each of the plurality of word line structures includes a conductive layer, a cap layer disposed on the conductive layer and a dielectric liner layer surrounding the conductive layer and the cap layer. The plurality of source/drain areas are disposed in the plurality of active areas and disposed on opposite sides of each of the plurality of word line structures.

In some embodiments, a sidewall of an upper portion of each of the word line structures is surrounded by the semiconductor material layer.

In some embodiments, a top surface of the conductive layer is higher than a bottom surface of each of the plurality of source/drain areas.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. The disclosure can be more fully understood by reading the following detailed description of the embodiment, with reference made to the accompanying drawings as follows.

FIG. 1 is a top view of a semiconductor structure including a plurality of active areas according to some embodiments of this disclosure,

FIGS. 2 and 3 are cross-sectional views taken along a section-line NN′ of FIG. 1 of a method of manufacturing a semiconductor structure during forming a semiconductor material layer according some embodiments of the present disclosure,

FIGS. 4 and 5 are cross-sectional views taken along a section-line NN′ of FIG. 1 of a method of manufacturing a semiconductor structure during forming an insulating layer according some embodiments of the present disclosure,

FIG. 6 is a top view of a semiconductor structure including a plurality of word line structures according to some embodiments of this disclosure, and

FIGS. 7 and 8 are cross-sectional views taken along a section-line NN′ of FIG. 6 of a method of manufacturing a semiconductor structure during forming a plurality of word line structures according some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The words “comprise”, “include”, “have”, “contain” and the like used in the present disclosure are open terms, meaning including but not limited to.

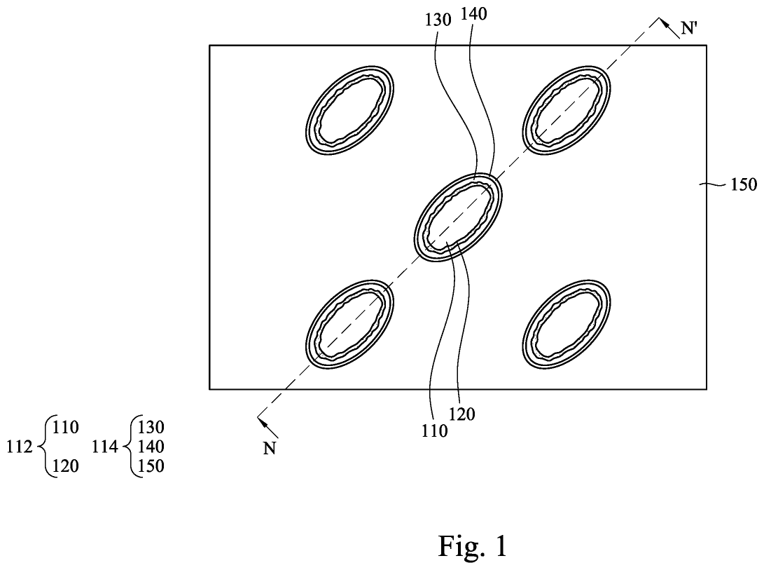

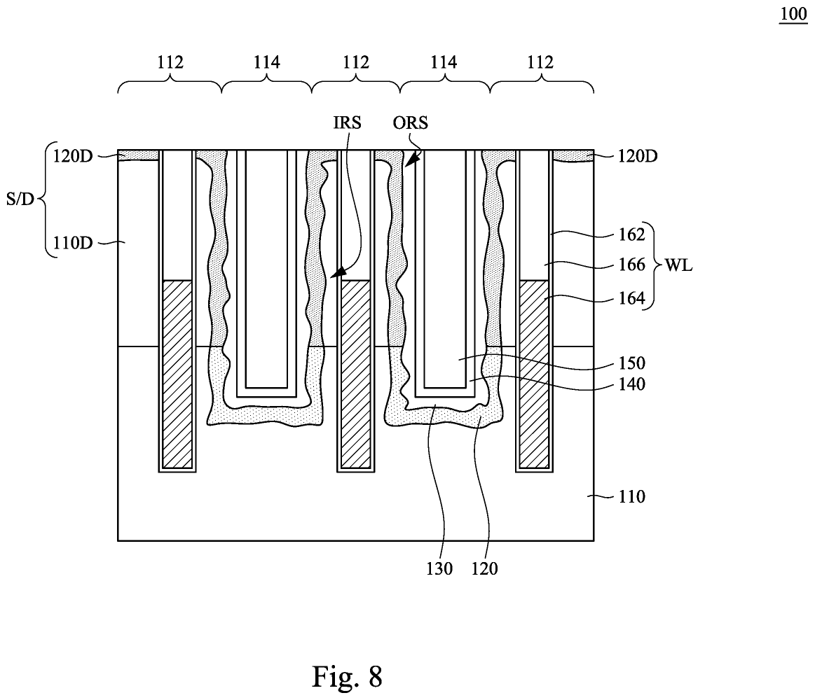

It should be noted that when the following figures, such as FIGS. 1 to 8, are illustrated and described as a series of operations or steps, the description order of these operations or steps should not be limited. For example, some operations or steps may be undertaken in a different order than in the present disclosure, or some operations or steps may occur currently, or some operations may not be used, and/or some operations or steps may be repeated. Moreover, the actual operations or steps of process stages may require additional operations or steps before, during or after forming the semiconductor structure (for example, a semiconductor structure 100 in FIG. 8) to completely form the semiconductor structure 100. Therefore, the present disclosure may briefly illustrate some of these additional operations or steps. Further, unless otherwise stated, the same explanations discussed for the following figures, such as FIGS. 1 to 8, apply directly to the other figures.

Since components of a semiconductor structure are getting denser and denser, for example, when manufacturing active areas of the semiconductor structure, shallow trench isolation (STI) areas are designed to be denser and denser, a layer of Si, such as polysilicon, is first be grown in the STI areas to protect the substrate of the STI areas and also increase landing areas of word lines. However, chlorine is a by-product during growing the layer of Si. The chlorine has corrosive damage at high temperature, so that surfaces of the STI areas become rough. The rough surfaces of the STI areas make the STI areas not straight enough, which in turn affects the landing areas of the word lines. In order to solve the problem, embodiments of this disclosure provide a solution to add a layer of oxide, such as SiO₂, on a surface of the layer of Si in a short time and at high-temperature. This solution allows the surface of each of STI areas to be modified and defined by the layer of the oxide. Moreover, the protection of the additional layer of the oxide also enhances the protection of STI areas to avoid Si consumption due to oxidation.

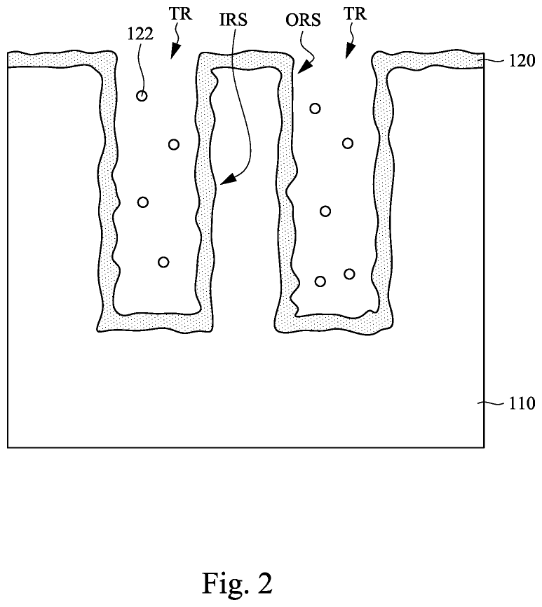

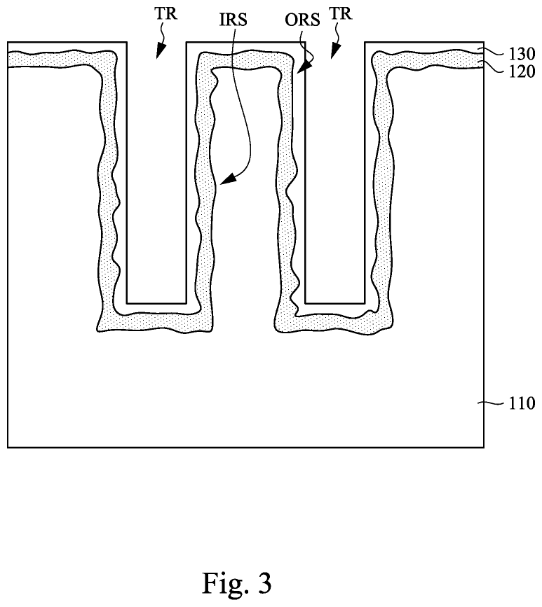

Please refer to FIGS. 1-3. FIG. 1 is a top view of a semiconductor structure including a plurality of active areas according to some embodiments of this disclosure, and FIGS. 2 and 3 are cross-sectional views taken along a section-line NN′ of FIG. 1 of a method of manufacturing a semiconductor structure during forming a semiconductor material layer according some embodiments of the present disclosure. In FIG. 2, a substrate 110 is provided for forming a plurality of trenches TR in the substrate. The substrate 110 is a semiconductor material, which may include silicon, such as crystalline silicon, polycrystalline silicon or amorphous silicon. In some embodiments, the substrate 110 may include an elemental semiconductor, such as germanium (Ge). In some embodiments, the substrate 110 may include alloy semiconductors such as silicon germanium (SiGe), silicon carbide phosphide (SiPC), gallium arsenide phosphide (GaAsP), aluminum indium arsenide (AlInAs), aluminum gallium arsenide (AlGaAs), gallium arsenide Indium gallium (GaInAs), gallium indium phosphide (GalnP), gallium indium phosphide (GaInAsP), or other suitable materials. In some embodiments, the substrate 110 may include compound semiconductors such as silicon carbide (SiC), silicon phosphide (SiP), gallium arsenide (GaAs), gallium phosphide (GaP), indium phosphide (InP), indium arsenide (InAs), Indium antimonide (InSb), zinc oxide (ZnO), zinc selenide (ZnSe), zinc sulfide (ZnS), zinc telluride (ZnTe), cadmium selenide (CdSe), cadmium sulfide (CdS), cadmium telluride (CdTe) or other suitable materials.

Next, a semiconductor material layer 120 is formed on an inner surface of each of the trenches TR and a top surface of the substrate 110. An inner surface IRS of the semiconductor material layer 120 directly contacts the inner surface of each of the trenches TR in the substrate 110, and an outer surface ORS of the semiconductor material layer 120 is exposed by each of the trenches. During forming the semiconductor material layer 120, chloride 122, a by-product, is produced. Moreover, the inner surface IRS and the outer surface ORS of the semiconductor material layer 120 are roughened by the chloride 122. In some embodiments, the semiconductor material layer 120 includes polysilicon. In some embodiments, a thickness of the semiconductor material layer 120 is from 55 angstroms (Å) to 80 Å.

In FIG. 3, a first barrier layer 130 is conformally deposited on the semiconductor material layer 120. An inner surface of the first barrier layer 130 directly contacts the outer surface ORS of the semiconductor material layer 120, and the inner surface of the first barrier layer 130 and the outer surface ORS of the semiconductor material layer 120 are conformal. Additionally, an outer surface of the first barrier layer 130 is substantially even. In some embodiments, the first barrier layer 130 includes oxide, such as SiO₂. In some embodiments, the thickness of the semiconductor material layer 120 is greater than a thickness of the first barrier layer 130. In some embodiments, a thickness of the first barrier layer 130 is from 15 Å to 20 Å. In some embodiments, the first barrier layer 130 is deposited by atomic layer deposition (ALD). In some embodiments, the first barrier layer 130 is deposited at a high temperature, such as 800° C. Through disposing the first barrier layer 130, the continued generation of the chloride 122 may be reduced and a surface of an insulation area (such as each of the insulation areas 114 in FIG. 1) formed in subsequent processes may be straight.

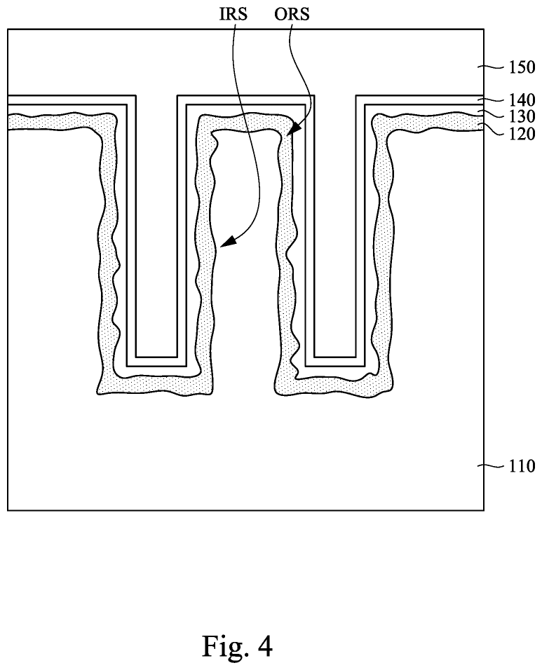

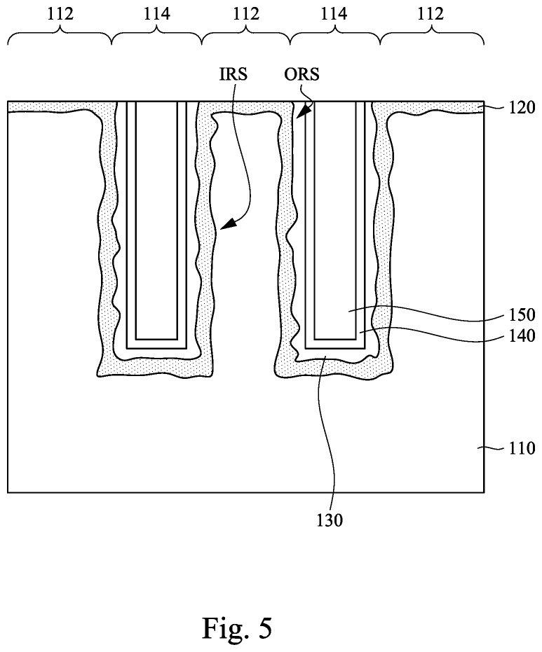

Further, please refer to FIGS. 4 and 5. FIGS. 4 and 5 are cross-sectional views taken along a section-line NN′ of FIG. 1 of a method of manufacturing a semiconductor structure during forming an insulating layer according some embodiments of the present disclosure. In FIG. 4, a second barrier layer 140 is conformally deposited on the first barrier layer 130. In some embodiments, a thickness of the second barrier layer 140 is greater than the thickness of the first barrier layer 130. In some embodiments, the thickness of the second barrier layer 140 is from 80 Å to 90 Å. In some embodiments, the second barrier layer 140 includes oxide, such as SiO₂. In some embodiment, a content of the oxide of the second barrier layer 140 is different from a content of the oxide of the first barrier layer 130. In some embodiments, the second barrier layer 140 is deposited by chemical vapor deposition (CVD), physical vapor deposition (PVD), ALD or any suitable deposition process. In some embodiment, a deposition process for forming the second barrier layer 140 is different from a deposition process for forming the first barrier layer 130. In some embodiments, the second barrier layer 140 is deposited at a temperature, such as 600° C., lower than the temperature during depositing the first barrier layer 130.

Furthermore, in FIG. 4, an insulating layer 150 is deposited on the second barrier layer 140, and a top surface of the insulating layer 150 is higher than a topmost surface of the second barrier layer 140. In some embodiments, the insulating layer 150 includes oxide, such as SiO₂. In some embodiments, the insulating layer 150 is deposited by chemical vapor deposition (CVD), physical vapor deposition (PVD), ALD or any suitable deposition process. In some embodiments, a deposition process for forming the insulating layer 150 is as the same as the deposition process for forming the second barrier layer 140. In some embodiment, a content of the oxide of the insulating layer 150 is as the same as the content of the oxide of the second barrier layer 140.

In FIG. 5, a planarization process is performed on the insulating layer 150 until exposing a topmost surface of the semiconductor material layer 120 after depositing the insulating layer 150 to form a plurality of insulation areas 114 in the substrate 110. Moreover, as shown in the top view of FIG. 1, a plurality of active areas 112 are formed and surrounded by the insulation areas 114. Additionally, a boundary between each of the active areas 112 and each of the insulation areas 114 is substantially based on the outer surface ORS of the semiconductor material layer 120. In other words, each of the active areas 112 is defined from one outer surface ORS to the closest outer surface ORS without across the first barrier layer 130, the second barrier layer 140 and the insulating layer 150, while each of the insulation areas 114 is defined from one outer surface ORS to the closest outer surface ORS across the first barrier layer 130. In some embodiments, the planarization process includes chemical mechanical polishing or any suitable planarization process. Further, the topmost surface of the semiconductor material layer 120, a top surface of the first barrier layer 130, a top surface of the second barrier layer 140 and a top surface of the insulating layer 150 are coplanar after the planarization process. The topmost surface of the semiconductor material layer 120 becomes even after the planarization process.

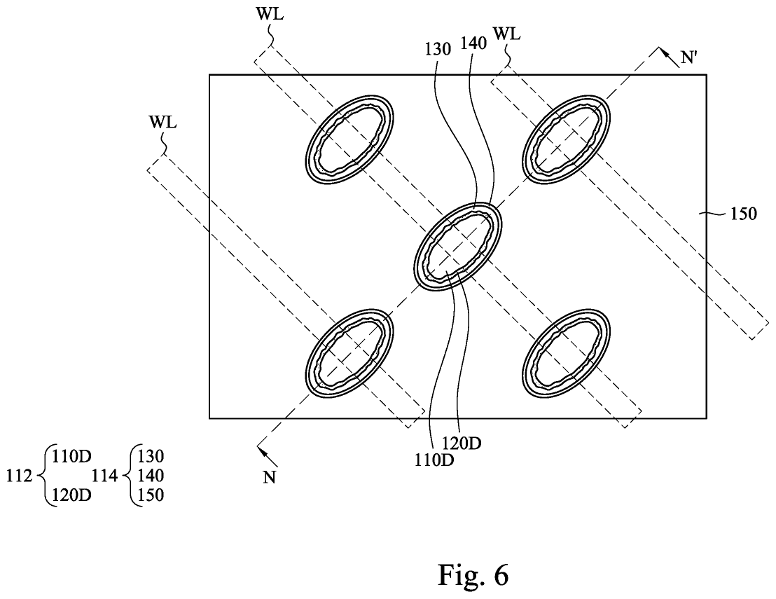

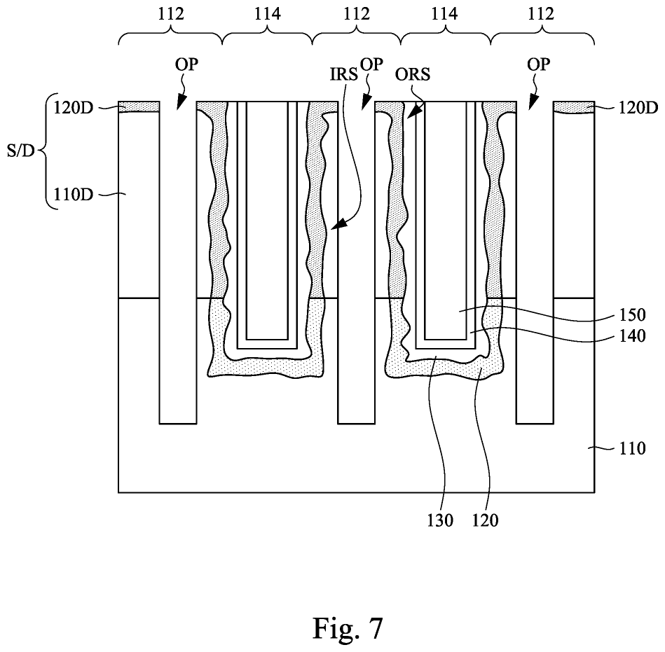

Next, please refer to FIGS. 6 to 8. FIG. 6 is a top view of a semiconductor structure including a plurality of word line structures according to some embodiments of this disclosure, and FIGS. 7 and 8 are cross-sectional views taken along a section-line NN′ of FIG. 6 of a method of manufacturing a semiconductor structure during forming a plurality of word line structures according some embodiments of the present disclosure. In FIG. 7, a plurality of source/drain areas S/D are formed in the active areas 112 of the substrate 110. Specifically, an ion implantation process may be performed on an upper portion of the substrates 110 and an upper portion of the semiconductor material layer 120 to dope N-type or P-type dopants into the active areas 112 of the substrate 110 to form a doped region 110D and a doped semiconductor material layer 120D, respectively. Further, the doped region 110D and the doped semiconductor material layer 120D are collectively referred to as each of the source/drain areas S/D. In some embodiments, the N-type dopants may include phosphorus or arsenic, and the P-type dopants include boron or boron fluoride.

Further, combined the top view of FIG. 6 with FIG. 7, a plurality of openings OP corresponding to a plurality of word line structures WL are formed, and the openings OP are extended through the insulation areas 114 and the active areas 112. Moreover, as shown in FIG. 7, based on the section-line NN′, the openings OP are formed in the active areas 112, and a bottom surface of each of the openings OP is lower than a bottom surface of the semiconductor material layer 120.

In FIG. 8, a dielectric liner layer 162 is formed on an inner surface of each of the openings OP (such as in FIG. 7). In some embodiments, the dielectric liner layer 162 may include silicon oxide or high dielectric constant materials. In some embodiment, the high dielectric constant materials are hafnium oxide (HfO₂), zirconium oxide (ZrO₂), tantalum pentoxide (Ta₂O₅) or a combination thereof. The dielectric liner layer 162 is formed by CVD process, ALD process, oxygen plasma oxidation process, thermal oxidation process, other suitable techniques, or a combination thereof.

Next, a conductive layer 164 is formed within each of the openings OP (such as in FIG. 7) and on the dielectric liner layer 162. The dielectric liner layer 162 surrounds a sidewall and a bottom surface of the conductive layer 164. In addition, the conductive layer 164 at least partially overlaps with each of the source/drain areas S/D, that is, each of the source/drain areas S/D is disposed on opposite sides of the conductive layer 164. In some embodiments, the conductive layer 164 is formed of any suitable conductive material, such as semiconductor, metal, metal nitride, metal silicide, other suitable conductive materials or a combination thereof. For example, the conductive layer 164 may include doped polysilicon, titanium (Ti), tungsten (W), tantalum (Ta), titanium nitride (TiN), tungsten nitride (WN), tantalum nitride (TaN), Titanium silicon nitride (TiSiN), tantalum silicon nitride (TaSiN), tungsten silicon nitride (WSiN), other suitable conductive materials or a combination thereof.

Further, a cap layer 166 is formed within each of the openings OP (such as in FIG. 7) and stacks on the conductive layer 164, and a bottom surface of the cap layer 166 directly contacts a top surface of the conductive layer 164. Additionally, the dielectric liner layer 162 surrounds the sidewall and the bottom surface of the conductive layer 164 and a sidewall of the cap layer 166. In some embodiments, the material of the cap layer 166 may include silicon oxide, silicon nitride, silicon oxynitride or a combination thereof. Then, as shown in the top view of FIG. 6, each of the word line structures WL is linear and extends the insulation areas 114 and the active areas 112.

Furthermore, a semiconductor structure 100 including a semiconductor material layer 120 is provided. As shown in FIG. 8, the semiconductor structure 100 includes the plurality of active areas 112 and the plurality of insulation areas 114 surrounding the active areas 112. Each of the active areas 112 is disposed in the substrate 110 and surrounded by the semiconductor material layer 120, and the inner surface IRS of the semiconductor material layer 120 contacts each of the active areas 112 is rough. Also, the semiconductor material layer 120 is disposed on each of the active areas 112, and a top surface (a topmost surface) of the semiconductor material layer 120 of the each of the active areas 112 is higher than a top surface of each of the active areas 112 of the substrate 110. A top surface of the semiconductor material layer 120 on each of the active areas 112 is even, and a bottom surface of the semiconductor material layer 120 contacting each of the active areas 112 is rough.

Each of the insulation areas 114 is disposed in the substrate 110 and surrounding each of the plurality of active areas 112. Each of the insulation areas 114 includes the semiconductor material layer 120, the first barrier layer 130 on the semiconductor material layer 120, the second barrier layer 140 on the first barrier layer 130 and the insulating layer 150 on the second barrier layer 140. Moreover, a top surface and a bottom surface of the semiconductor material layer 120 of each of the insulation areas 114 are rough. In some embodiments, the top surface of the semiconductor material layer 120 of each of the active areas 112 and a top surface of the insulating layer 150 are coplanar.

Additionally, a surface of the first barrier layer 130 contacting the second barrier layer 140 is even, a surface of the first barrier layer 130 contacting the semiconductor material layer 120 and a surface of the semiconductor material layer disposed on a sidewall of each of the active areas 112 are conformal. That is, the surface of the first barrier layer 130 contacting the semiconductor material layer 120 is rough. Since the surface of the first barrier layer 130 contacting the second barrier layer 140 is even, both surfaces of the second barrier layer 140 are even. Further, a surface of the insulating layer 150 contacting the second barrier layer 140 is even. It is worth to mention that some features of the semiconductor material layer 120, the first barrier layer 130 and the second barrier layer 140 are described above, and here not repeated.

Further, the semiconductor structure 100 also includes a plurality of word line structures WL and a plurality of source/drain areas S/D in the active areas 112. Each of the word line structures WL extends through the insulation areas 114 and the active areas 112. Each of the word line structures WL includes a conductive layer 164, a cap layer 166 on the conductive layer 164 and a dielectric liner layer 162 surrounding the conductive layer and the cap layer. Specifically, a top surface of the conductive layer 164 directly contacts a bottom surface of the cap layer 166, and the dielectric liner layer 162 surrounding a sidewall and a bottom surface of the conductive layer 164 and a sidewall of the cap layer 166. In some embodiments, a sidewall of an upper portion of each of the word line structures WL is surrounded by the semiconductor material layer 120. Moreover, each of the source/drain areas S/D is disposed on opposite sides of each of the plurality of word line structures WL. In some embodiments, the top surface of the conductive layer 164 is higher than a bottom surface of each of the source/drain areas S/D.

As stated as above, in the embodiments of this disclosure, the surfaces of the insulation areas, such as STI areas, are modified into a straight structure by disposing a first barrier layer between the insulating layer and the semiconductor material layer (a polysilicon layer). Thus, the problem of the landing areas of the word lines can be solved. Also, the first barrier layer protects the surfaces of the insulation areas from oxidation, improving the protection of insulation areas.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a semiconductor structure, comprising:
forming a plurality of trenches in a substrate;
forming a semiconductor material layer on an inner surface of each of the plurality of trenches and a top surface of the substrate, wherein the semiconductor material layer has an inner rough surface contacting the substrate and an outer rough surface exposing by each of the plurality of trenches;
depositing a first barrier layer on the outer rough surface of the semiconductor material layer, wherein an outer surface of the first barrier layer is even; and
depositing a second barrier layer on the first barrier layer.

2. The method of claim 1, wherein the first barrier layer comprises oxide, and the second barrier layer comprises the oxide.

3. The method of claim 2, wherein a content of the oxide of the second barrier layer is different from a content of the oxide of the first barrier layer.

4. The method of claim 1, wherein a temperature for forming the first barrier layer is greater than a temperature for forming the second barrier layer.

5. The method of claim 1, wherein chloride is produced during forming the semiconductor material layer, and
wherein the inner rough surface and the outer rough surface of the semiconductor material layer are roughened by the chloride.

6. The method of claim 1, wherein an inner surface of the first barrier layer contacting the outer rough surface of the semiconductor material layer and the outer rough surface of the semiconductor material layer are conformal.

7. The method of claim 1, wherein a thickness of the semiconductor material layer is greater than a thickness of the first barrier layer.

8. The method of claim 1, further comprising:
depositing an insulating layer on the second barrier layer to form a plurality of insulation areas; and
planarizing the insulating layer until exposing a topmost surface of the semiconductor material layer to a plurality of active areas adjacent to each of the plurality of insulation areas.

9. The method of claim 8, wherein the topmost surface of the semiconductor material layer, a top surface of the first barrier layer, a top surface of the second barrier layer and a top surface of the insulating layer are coplanar.

10. The method of claim 8, further comprising:
forming a plurality of word line structures in the plurality of active areas after depositing the insulating layer.

11. A semiconductor structure, comprising:
a plurality of active areas, disposed in a substrate and surrounded by a semiconductor material layer, wherein a surface of the semiconductor material layer contacting each of the plurality of active areas is rough; and
a plurality of insulation areas, disposed in the substrate and surrounding each of the plurality of active areas, wherein each of the plurality of insulation areas comprises the semiconductor material layer, a first barrier layer on the semiconductor material layer and an insulating layer over the first barrier layer, and wherein a top surface of the semiconductor material layer and a bottom surface of the semiconductor material layer are rough.

12. The semiconductor structure of claim 11, wherein a top surface of the semiconductor material layer is higher than a top surface of the substrate.

13. The semiconductor structure of claim 11, wherein a top surface of the semiconductor material layer is even and coplanar with a top surface of the insulating layer.

14. The semiconductor structure of claim 11, wherein each of the plurality of insulation areas further comprises:
a second barrier layer, disposed between the first barrier layer and the insulating layer.

15. The semiconductor structure of claim 14, wherein one surface of the first barrier layer contacting a surface of the second barrier layer is even, and the other surface of the first barrier layer contacting the other surface of the semiconductor material layer disposed on a sidewall of each of the plurality of active areas are conformal.

16. The semiconductor structure of claim 11, wherein a thickness of the semiconductor material layer is from 55 angstroms to 80 angstroms.

17. The semiconductor structure of claim 11, wherein a thickness of the first barrier layer is from 15 angstroms to 20 angstroms.

18. The semiconductor structure of claim 11, further comprising:
a plurality of word line structures, extending through the insulation areas and the active areas, wherein each of the plurality of word line structures comprises:
a conductive layer;
a cap layer, disposed on the conductive layer; and
a dielectric liner layer, surrounding the conductive layer and the cap layer; and
a plurality of source/drain areas, disposed in the plurality of active areas and disposed on opposite sides of each of the plurality of word line structures.

19. The semiconductor structure of claim 18, wherein a sidewall of an upper portion of each of the word line structures is surrounded by the semiconductor material layer.

20. The semiconductor structure of claim 18, wherein a top surface of the conductive layer is higher than a bottom surface of each of the plurality of source/drain areas.
